(19) United States
(12) Patent Application Publication
(10) Pub. No.: US 2002/0125934 A1
(43) Pub. Date: Sep. 12, 2002

(54) Automatic substrate biasing circuit

(76) Inventors: Kap-Pin Wu, Tainan (TW); Sheng-Shiang Chiang, Kaohsiung (TW)

Correspondence Address: J.C. Patents, Inc., Suite 250, 4 Venture, Irvine, CA, 92618, US

(21) Appl. No.: 10/053,281

(22) Filed: Jan. 16, 2002

(30) Foreign Application Priority Data
Jan. 16, 2001 (TW) 90100910

(51) Int. Cl. H03K 3/01

(52) U.S. Cl. 327/534

(57) ABSTRACT

An automatic substrate biasing circuit, which detects the voltage source having the largest magnitude of voltage in the circuit, to bias the substrate voltage of the circuit to a desired level automatically based on the comparison result. A comparator is used in the present invention to compare different voltage sources to obtain a comparison result, which is subsequently received by a control circuit to selectively choose one of the voltage sources to control the switching operation of the switch, so that the largest voltage of the circuit can be obtained. This voltage is then used to bias the substrate voltage to a desired level.

### CROSS-REFERENCE TO RELATED APPLICATION

This application claims the priority benefit of Taiwan application serial no. 90100910, filed Jan. 16, 2001.

### BACKGROUND OF THE INVENTION

1. Field of Invention

The present invention generally relates to an automatic substrate biasing circuit, and more particularly, to a circuit capable of automatically biasing the substrate voltage to a desired level.

2. Description of Related Art

Thanks to advancements in integrated circuit design and the development of hybrid circuits, circuits using several voltage sources with different voltage levels are getting more and more popular. For example, charge pump, liquid crystal display driver, and mouse circuit, to name a few, are all using several voltage sources with different voltage levels to supply the required power for circuit operation. Generally, the largest operating voltage of the system is not clear when the circuit is initialized. Thus, how to bias the substrate voltage to a desired level to prevent the latch up effect due to the extra substrate current is a very important problem that needs to be solved.

FIG. 1 shows a circuit diagram of a conventional voltage comparator. Two different voltage sources, VDD and Vpp, are coupled to a ground voltage through two serial resistors R1-R2 and R3-R4, respectively. A comparator 8 is used to compare the magnitude of the voltage sources. Because the area that resistors take up is very large, the designing cost is significantly increased.

### SUMMARY OF THE INVENTION

It is therefore an objective of the present invention to provide a simple circuit to obtain a desired substrate voltage. To achieve the above objective, a comparator is used in the present invention to compare different voltage sources to obtain a comparison result, which is subsequently received by a control circuit to selectively choose one of the voltage sources to control the switching operation of the switch, so that the largest voltage of the circuit can be obtained. This voltage is then used to bias the substrate voltage to a desired level.

The present invention provides an automatic substrate biasing circuit to selectively choose which voltage source has a larger magnitude as between a first voltage source and a second voltage source, for use as a substrate voltage signal.

The automatic substrate biasing circuit comprises a comparator, a shift control circuit, and a switching circuit. The comparator receives a first voltage source and a second voltage source to generate a comparison signal. The shift control circuit receives the comparison signal and the substrate voltage signal to generate a first control signal and a second control signal. The switching circuit then receives the first voltage source, the second voltage source, the first control signal and the second control signal to generate a substrate voltage signal. The comparator mentioned above comprises a first PMOS transistor, a second PMOS transistor, a first NMOS transistor, and a second NMOS transistor. The source and the base of the first PMOS transistor are jointly coupled to a first voltage source, the gate of the first PMOS transistor is coupled to the drain of the first PMOS transistor. The source and the base of the second PMOS transistor are jointly coupled to a second voltage source, the gate of the second PMOS transistor is coupled to the gate of the first PMOS transistor, and the comparison signal is generated from the drain of the of the second PMOS transistor. The drain and the gate of the first NMOS transistor are jointly coupled to the drain of the first PMOS transistor, the source of first NMOS transistor is coupled to a ground voltage. The drain of the second NMOS transistor is coupled to the drain of the second PMOS transistor, the gate of the second NMOS transistor is coupled to the gate of the first NMOS transistor, and the source of the second NMOS transistor is coupled to the ground voltage.

The shift control circuit comprises a first inverter, a second inverter, and a third inverter. The first inverter receives the comparison signal and the substrate voltage signal to generate a first inverting signal. The second inverter receives the first inverting signal and the substrate voltage signal to provide a first control signal. The third inverter receives the first control signal and the substrate voltage signal to provide a second control signal. The Smith trigger can also be used to replace the first inverter mentioned above.

The shift control circuit comprises a third PMOS transistor, a fourth PMOS transistor, a third NMOS transistor, a fourth inverter, and a fourth NMOS transistor. The source of the third PMOS transistor is coupled to the substrate voltage signal, the drain of the third PMOS transistor generates a first control signal, and the gate of the third PMOS transistor generates a second control signal. The source of the fourth PMOS transistor is coupled to the substrate voltage signal, the drain of the fourth PMOS transistor is coupled to the gate of the third PMOS transistor, the gate of the fourth PMOS transistor is coupled to the drain of the third PMOS transistor. The drain of the third NMOS transistor is coupled to the drain of the third PMOS transistor, the gate of the third NMOS transistor receives the comparison signal, and the source of the third NMOS transistor is coupled to the ground voltage. The fourth inverter receives the comparison signal to generate a fourth inverting signal. The drain of the fourth NMOS transistor is coupled to the drain of the fourth PMOS transistor, the gate of the fourth NMOS transistor receives the fourth inverting signal, and the source of the fourth NMOS transistor is coupled to the ground voltage.

The switching circuit comprises a fifth PMOS transistor and a sixth PMOS transistor. The gate of the fifth PMOS transistor receives the first control signal, the source and the base of the fifth PMOS transistor are jointly coupled to the substrate voltage signal, and the drain of the fifth PMOS transistor is coupled to the first voltage source. The gate of the sixth PMOS transistor receives the second control signal, the source and the base of the sixth PMOS transistor are jointly coupled to the substrate voltage signal, and the drain of the sixth PMOS transistor is coupled to the second voltage source.

In addition, the present invention also includes another embodiment of the automatic substrate biasing circuit to selectively choose the voltage source having a larger magnitude between a first voltage source and a second voltage source for use as a substrate voltage signal.

The automatic substrate biasing circuit comprises a comparator, a shift control circuit, and a switching circuit. The comparator receives a first voltage source and a second voltage source to generate a comparison signal. The shift control circuit receives the comparison signal and the substrate signal to generate a first control signal and a second control signal. The switching circuit receives the first voltage source, the second voltage source, the first control signal and the second control signal to generate a substrate voltage signal. The comparator can also comprise a current source, a first PMOS transistor, a second PMOS transistor, a first NMOS transistor, and a second NMOS transistor. The current source generates a reference current. The source and the base of the first PMOS transistor are jointly coupled to the first voltage source, the gate of the first PMOS transistor is coupled to the drain of the first PMOS transistor. The source and the base of the second PMOS transistor are jointly coupled to the second voltage source, the gate of the second PMOS transistor is coupled to the gate of the first PMOS transistor, and the comparison signal is generated from the drain of the second PMOS transistor. The drain and the gate of the first NMOS transistor are jointly coupled to the current source, the source of the first NMOS transistor is coupled to the ground voltage. The drain of the second NMOS transistor is coupled to the drain of the first PMOS transistor, the gate of the second NMOS transistor is coupled to the gate of the first NMOS transistor, and the source of the second NMOS transistor is coupled to the ground voltage. The drain of the third NMOS transistor is coupled to the drain of the second PMOS transistor, the gate of the third NMOS transistor is coupled to the gate of the first NMOS transistor, and the source of the third NMOS transistor is coupled to the ground voltage.

The shift control circuit, with the same construction as mentioned above, comprises three inverters or two PMOS transistors, two NMOS transistors, and one inverter. The switching circuit, with the same construction as mentioned above, comprises two PMOS transistors.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1 is a circuit diagram of a conventional voltage comparator;

FIG. 2 is a schematic block diagram of the automatic substrate biasing circuit according to a preferred embodiment of the present invention;

FIG. 3A is a circuit diagram showing an embodiment of the comparator in FIG. 2;

FIG. 3B is a circuit diagram showing another embodiment of the comparator in FIG. 2;

FIG. 4A is a diagram showing an embodiment of the shift control circuit in FIG. 2;

FIG. 4B is a circuit diagram showing another embodiment of the shift control circuit in FIG. 2;

FIG. 5 is a circuit diagram showing an embodiment of the switching circuit in FIG. 2;

FIG. 6 is a circuit diagram showing a preferred embodiment of the automatic substrate biasing circuit in FIG. 2; and

FIG. 7 is a diagram showing the simulation result of the automatic substrate biasing circuit shown in FIG. 6 according to the present invention.

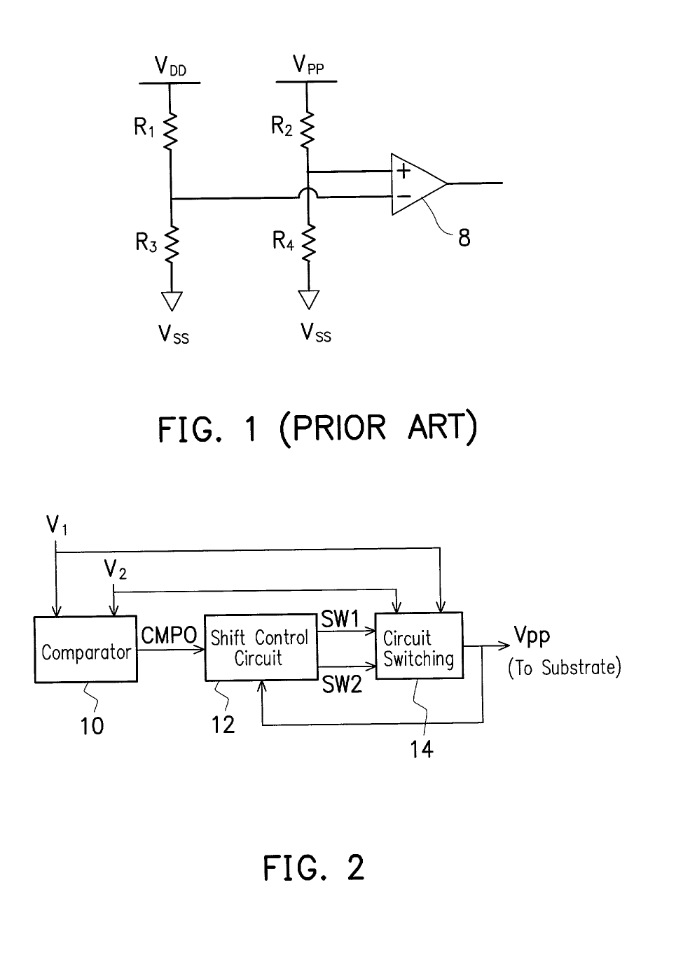

### DESCRIPTION OF THE PREFERRED EMBODIMENTS

Referring to FIG. 2, it shows a schematic block diagram of the automatic substrate biasing circuit according to a preferred embodiment of the present invention.

The automatic substrate biasing circuit according to the present invention selectively chooses the voltage source having a larger magnitude between a first voltage source V1 and a second voltage source V2 for use as a substrate voltage signal Vpp. As shown in the diagram, the automatic substrate biasing circuit according to the present invention comprises a comparator 10, a shift control circuit 12, and a switching circuit 14.

While the circuit is working, the comparator 10 generates a comparison signal CMPO to use to choose the highest voltage circuit as between the first voltage source V1 and the second voltage source V2. The comparison signal CMPO is subsequently received by the shift control circuit 12. The shift control circuit 12 then provides a first control signal SW1 and a second control signal SW2 to the switching circuit 14 based on the received comparison signal CMPO. The magnitudes of the first control signal SW1 and the second control signal SW2 are used to control the switch turning on or off. The switching circuit 14 selectively chooses the voltage source having larger magnitude as between the first voltage source V1 and the second voltage source V2, to use as the substrate voltage signal Vpp based on the first control signal SW1 and the second control signal SW2. Furthermore, the substrate voltage signal Vpp is coupled to the shift control circuit 12 to supply power to the shift control circuit 12.

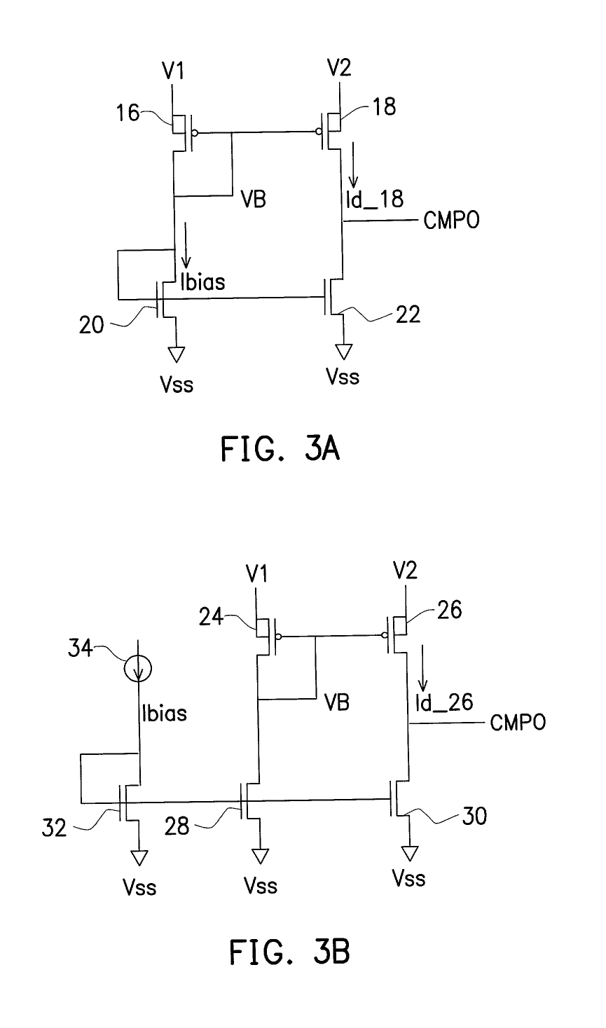

FIG. 3A shows a circuit diagram of a comparator in FIG. 2. As shown in the diagram, the comparator comprises two PMOS transistors 16, 18, and two NMOS transistor 20, 22. The source and the base of the PMOS transistor 16 are jointly coupled to the first voltage source V1, the gate of the PMOS transistor 16 is coupled to the drain of the PMOS transistor 16. The source and the base of PMOS transistor 18 are jointly coupled to the second voltage source V2, the gate of the PMOS transistor 18 is coupled to the gate of the PMOS transistor 16, and the comparison signal CMPO is generated from the drain of the PMOS transistor 18. The drain and the gate of the NMOS transistor 20 are jointly coupled to the drain of the PMOS transistor 16, the source of the NMOS transistor 20 is coupled to the ground voltage Vss. The drain of the NMOS transistor 22 is coupled to the drain of the PMOS transistor 18, the gate of the NMOS transistor 22 is coupled to the gate of the NMOS transistor 20. The source of the NMOS transistor 22 is coupled to the ground voltage Vss.

While operating, the transistors 16, 18, 20 and 22 work together as a voltage comparator. The Ibias in the FIG. 3A is determined by the aspect ratio of the transistors 16 and 20. If V2>V1, then Vgs_18>Vgs_16, where the Vgs_18 is the voltage difference between the gate and the source of the PMOS transistor 18, the Vgs_16 is the voltage difference between the gate and the source of the PMOS transistor 16. It is because the PMOS transistors 16, 18 are the match devices, which do not have the body effect, that the threshold voltage Vt is also matched. Therefore, Id_18>Ibias, thus CMPO is raised to the high magnitude of voltage. Contrariwise, if V2<V1, the CMPO will be pulled down to the low magnitude of voltage.

The FIG. 3B is a circuit diagram showing another embodiment of the comparator in FIG. 2. As shown in the diagram, the comparator comprises two PMOS transistors 24, 26, three NMOS transistors 28, 30 and 32, and a current source 34. The current source 34 generates a reference current Ibias. The source and the base of the PMOS transistor 24 are jointly coupled to the first voltage source V1, the gate of the PMOS transistor 24 is coupled to the drain of the PMOS transistor 24. The source and the base of the PMOS transistor 26 are jointly coupled to the second voltage source V2, the gate of the second PMOS transistor 26 is coupled to the gate of the PMOS transistor 24, and the comparison signal CMPO is generated from the drain of the second PMOS transistor 26. The drain and the gate of the NMOS transistor 32 are jointly coupled to the current source 34, the source of the NMOS transistor 32 is coupled to the ground voltage Vss. The drain of the NMOS transistor 28 is coupled to the drain of the PMOS transistor 24, the gate of the NMOS transistor 28 is coupled to the gate of the NMOS transistor 32, and the source of the NMOS transistor 28 is coupled to the ground voltage Vss. The drain of the NMOS transistor 30 is coupled to the drain of the PMOS transistor 26, the gate of the NMOS transistor 30 is coupled to the gate of the NMOS transistor 32, and the source of the NMOS transistor 30 is coupled to the ground voltage Vss.

The other comparator circuit diagram shown in FIG. 3B mirrors the current of the drain of the NMOS transistors 28, 30 to the Ibias by using the Ibias that is generated by the current source. Thus the bias VB is generated via the PMOS transistor 24, in which

$$V 1 - VB = Vt + \sqrt{\frac{Ibias}{\frac{1}{2} μ nCox * \frac{W}{L}}} = Vgs\_ 24$$

Consequently, when V2>V1, Vgs_26 is

$$Vgs\_ 26 = Vgs\_ 24 + ( V 2 - V 1 ) = Vt + \sqrt{\frac{Ibias}{\frac{1}{2} μ nCox * \frac{W}{L}}} + ( V 2 - V 1 )$$

$$Therefore , Id\_ 26 = \frac{1}{2} μ nCox ( \frac{W}{L} ) {( Vgs\_ 26 - {V}_{T} )}^{2} = Ibias + Δ I ;$$

$$In which , Δ I = 2 \sqrt{\frac{1}{2} μ nCox ( \frac{W}{L} ) Ibias} * ( V 2 - V 1 ) + \frac{1}{2} μ nCox ( \frac{W}{L} ) {( V 2 - V 1 )}^{2}$$

Therefore, Id_26=Ibias+ΔI>Ibias, thus the CMOP is raised to the high magnitude of the voltage. Contrariwise, if V2<V1, the CMPO is pulled down to the low magnitude of the voltage.

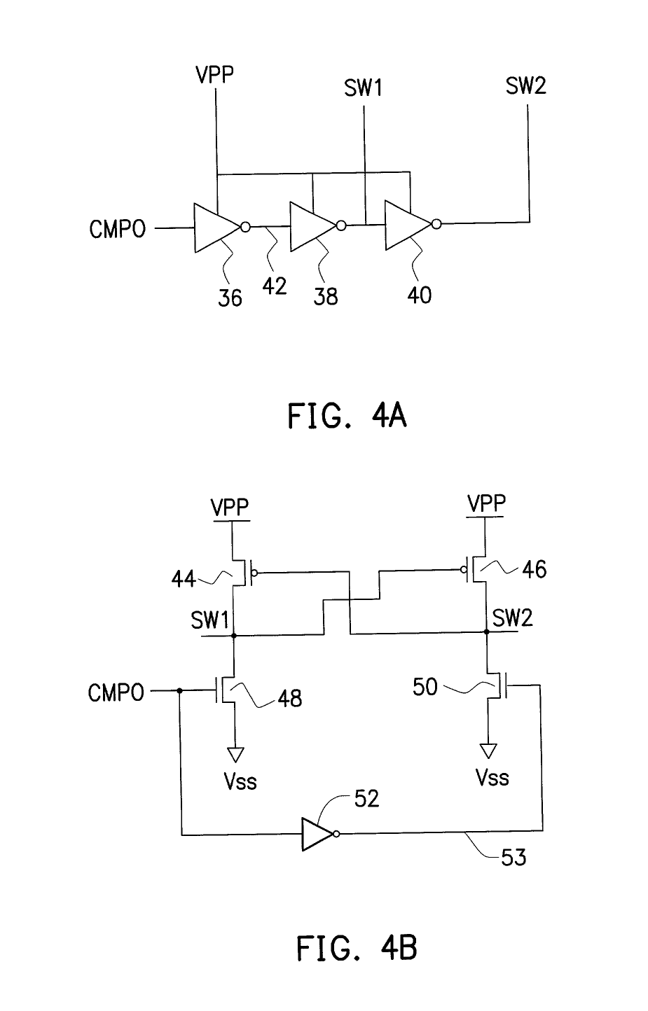

Furthermore, the FIG. 4A shows another circuit diagram of the shift control circuit in FIG. 2. As shown in the diagram, the shift control circuit comprises three inverters 36, 38 and 40. The first inverter 36 receives the comparison signal CMPO and the substrate voltage signal Vpp to generate the first inverting signal 42. The second inverter 38 receives the first inverting signal 42 and the substrate voltage signal Vpp to generate the first control signal SW1. The third inverter 40 receives the first control signal SW1 and the substrate voltage signal Vpp to generate the second control signal SW2.

The FIG. 4B shows another circuit diagram of the shift control circuit in FIG. 2. As shown in the diagram, the shift control circuit comprises two PMOS transistors 44, 46, two NMOS transistors 48, 50, and an inverter 52. The source of the PMOS transistor 44 is coupled to the substrate voltage signal Vpp, the first control signal SW1 is generated from the drain of the PMOS transistor 44, and the second control signal SW2 is generated from the gate of the PMOS transistor 44. The source of the PMOS transistor 46 is coupled to the substrate voltage Vpp, the drain of the PMOS transistor 46 is coupled to the gate of the PMOS transistor 44, the gate of the PMOS 46 is coupled to the drain of the PMOS transistor 44. The drain of the NMOS transistor 48 is coupled to the drain of the PMOS transistor 44, the gate of the NMOS transistor 48 receives the comparison signal CMPO, and the source of the NMOS transistor 48 is coupled to the ground voltage Vss. The inverter 52 then receives the comparison signal to generate an inverting signal 53. The drain of the NMOS transistor 50 is coupled to the drain of the PMOS transistor 46, the gate of the NMOS transistor 50 receives the inverting signal 53, and the source of the NMOS transistor 50 is coupled to the ground voltage Vss.

In order to prevent the CMPO from being interfered with by the power noise of the voltage source from generating the wrong signal, the first inverter 36 in the circuit diagram of the control circuit of the FIG. 4A also can be replaced by the Smith trigger, which is coupled to the CMPO. Furthermore, in order to control the switching circuit efficiently, the operating voltage of the control circuit must be the largest magnitude of voltage Vpp of the system. The Vpp does not have to provide a large magnitude of current due to the fact that the control circuit only consumes little current in the transit state and does not even consume current in the solid state.

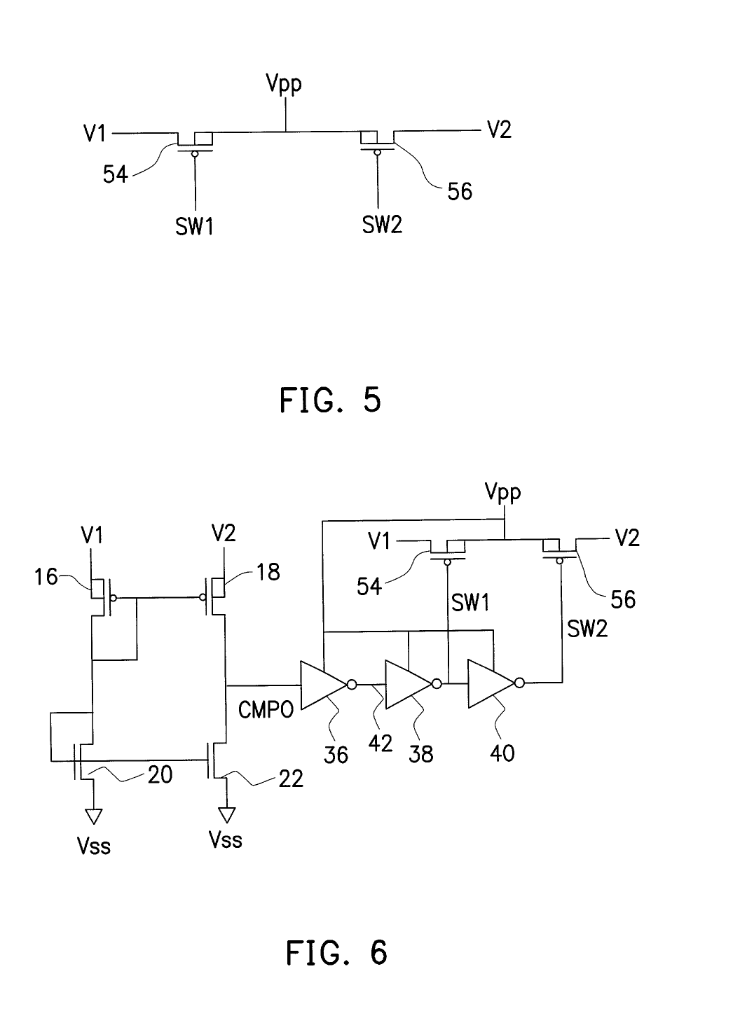

The FIG. 5 shows a circuit diagram of the switching circuit in FIG. 2. As shown in the diagram, the switching circuit comprises two PMOS transistors 54 and 56. The gate of the PMOS transistor 54 receives the first control signal SW1, the source and the base of the PMOS transistor 54 are jointly coupled to the substrate voltage signal Vpp, and the drain of the PMOS transistor 54 is coupled to the first voltage source V1. The gate of the PMOS transistor 56 receives the second control signal SW2, the source and the base of the PMOS transistor 56 are jointly coupled to the substrate voltage signal Vpp, and the drain of the PMOS transistor 56 is coupled to the second voltage source V2.

In FIG. 5, the PMOS transistors 54, 56 control the path of V1, V2 to Vpp respectively. If V2>V1, then SW2=0V, SW1=Vpp, so Vpp=V2. Contrariwise, if V2<V1, then Vpp=V1. It is worth noting that SW1, SW2 have to be raised to the magnitude of the Vpp. Otherwise, the switch cannot be turned off efficiently.

As long as the Vpp is generated, it is used as the substrate voltage of the PMOS. Thus prevents the substrate of the PMOS from generating the forwarding current that results in the latch up effect. In case there is a variation in V1 and V2, the circuit according to the present invention also can detect and respond immediately to the change in the magnitude of Vpp, to insure the circuit works correctly.

In order to have a better understanding about the automatic substrate biasing circuit according to a preferred embodiment of the present invention, FIG. 6 is used to represent the actual circuit diagram of the schematic block diagram in FIG. 2. Herein, FIG. 3A is selectively chosen as the embodiment of the comparator from FIG. 3A and FIG. 3B. The FIG. 4A is selectively chosen as the embodiment of the control circuit from FIG. 4A and FIG. 4B. As the function of each component that is represented by the same number in FIG. 6 is mentioned clearly above this will not be repeated here again.

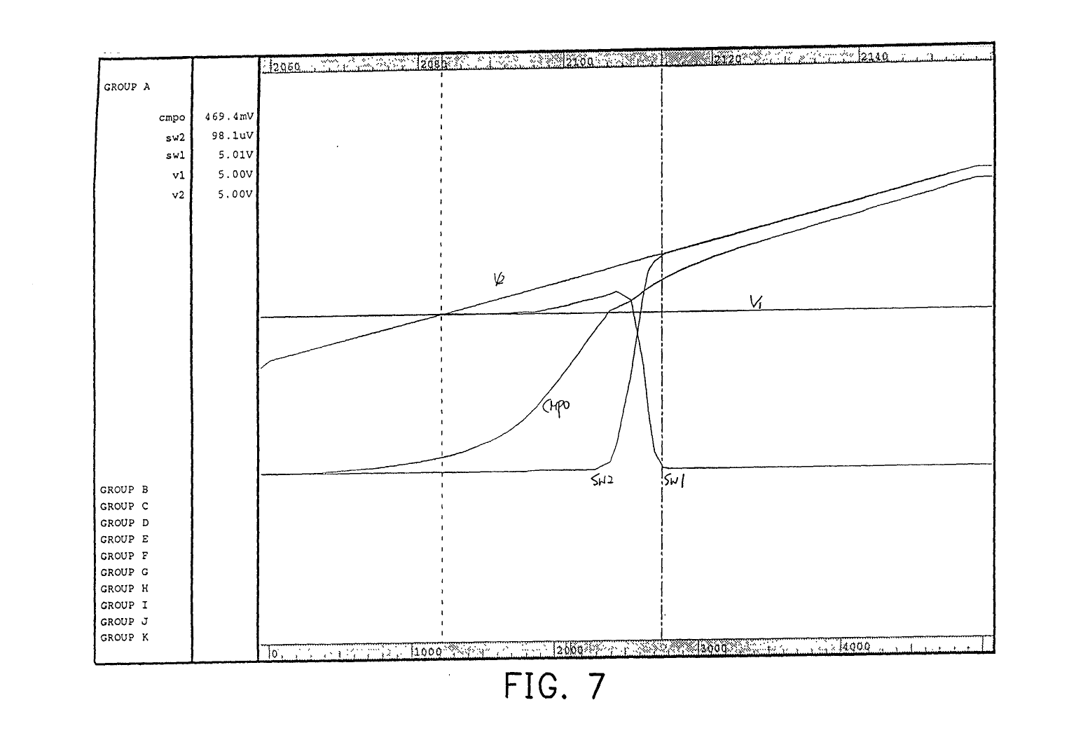

The FIG. 7 shows the simulation result of the automatic substrate biasing circuit according to the embodiment of the present invention. In FIG. 7, if V2>V1, the CMPO becomes the high magnitude of voltage, thus pushing SW2 to the low magnitude of voltage, and SW1 to the high magnitude of voltage. Therefore, the magnitude of Vpp is changed from the magnitude of V1 to the magnitude of V2.

The automatic substrate biasing circuit of the present invention uses a comparator to compare different voltage sources to obtain a comparison result, which is subsequently received by a control circuit to selectively choose one of the voltage sources to control the switching operation of the switch, so that the largest voltage of the circuit can be obtained. This voltage is then used to bias the substrate voltage to a desired level.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. An automatic substrate biasing circuit for use in integrated circuit devices to bias a substrate voltage to a desired level, comprising:
a comparator, which compares a plurality of voltage sources to generate a comparison signal;
a shift control circuit, which generates a plurality of control signals corresponding to the voltage sources according to the comparison signal; and
a switching circuit, which selectively determines one of the voltage sources as the substrate voltage according to the control signals;
wherein the substrate voltage is coupled to the shift control circuit to supply power to the shift control circuit.

2. The automatic substrate biasing circuit as claimed in claim 1, wherein the comparator comprises:
a first PMOS transistor having a gate, source, base and drain, wherein the source and the base of the first PMOS transistor are jointly coupled to a first voltage source, the gate of the first PMOS transistor is coupled to the drain of the first PMOS transistor;
a second PMOS transistor having a gate, source, base and drain, wherein the source and the base of the second PMOS transistor are jointly coupled to a second voltage source, the gate of the second PMOS transistor is coupled to the gate of the first PMOS transistor, the comparison signal is generated from the drain of the second PMOS transistor;
a first NMOS transistor having a gate, source, and drain, wherein the drain and the gate of the first NMOS transistor are jointly coupled to the drain of the first PMOS transistor, the source of the first NMOS transistor is coupled to a ground voltage; and
a second NMOS transistor having a gate, source, and drain, wherein the drain of the second NMOS transistor is coupled to the drain of the second PMOS transistor, the gate of the second NMOS transistor is coupled to the gate of the first NMOS transistor, and the source of the second NMOS transistor is coupled to the ground voltage.

3. The automatic substrate biasing circuit as claimed in claim 1, wherein the comparator comprises:
a current source for generating a reference current;
a first PMOS transistor having a gate, source, base and drain, wherein the source and the base of the first PMOS transistor are jointly coupled to a first voltage source, the gate of the first PMOS transistor is coupled to the drain of the first PMOS transistor;
a second PMOS transistor having a gate, source, base and drain, wherein the source and the base of the second PMOS transistor are coupled to a second voltage source, the gate of the second PMOS transistor is coupled to the gate of the first PMOS transistor, and the comparison signal is generated from the drain of the second PMOS transistor;
a first NMOS transistor having a gate, source, and drain, wherein the drain and the gate of the first NMOS transistor are coupled to the current source, the source of the first NMOS transistor is coupled to the ground voltage;
a second NMOS transistor having a gate, source, and drain, wherein the drain of the second NMOS transistor is coupled to the drain of the first PMOS transistor, the gate of the second NMOS transistor is coupled to the gate of the first NMOS transistor, and the source of the second NMOS transistor is coupled to the ground voltage; and
a third NMOS transistor having a gate, source, and drain, wherein the drain of the third NMOS transistor is coupled to the drain of the second PMOS transistor, the gate of the third NMOS transistor is coupled to the gate of the first NMOS transistor, and the source of the third NMOS transistor is coupled to the ground voltage.

4. The automatic substrate biasing circuit as claimed in claim 1, wherein the shift control circuit comprises:
a first inverter for receiving the comparison signal and the substrate voltage signal to generate a first inverting signal;
a second inverter for receiving the first inverting signal and the substrate voltage signal to generate a first control signal; and
a third inverter for receiving the first control signal and the substrate voltage signal to generate a second control signal.

5. The automatic substrate biasing circuit as claimed in claim 1, wherein the first inverter comprises a Smith trigger circuit.

6. The automatic substrate biasing circuit as claimed in claim 1, wherein the shift control circuit comprises:
a third PMOS transistor having a gate, source, and drain, wherein the source of the third PMOS transistor is coupled to the substrate voltage signal, the first control signal is generated from the drain of the third PMOS transistor, and the second control signal is generated from the gate of the third PMOS transistor;
a fourth PMOS transistor having a gate, source, and drain, wherein the source of the fourth PMOS transistor is coupled to the substrate voltage signal, the drain of the fourth PMOS transistor is coupled to the gate of the third PMOS transistor, and the gate of the fourth PMOS transistor is coupled to the drain of the third PMOS transistor;
a third NMOS transistor having a gate, source, and drain, wherein the drain of the third NMOS transistor is coupled to the drain of the third PMOS transistor, the gate of the third NMOS transistor receives the comparison signal, and the source of the third NMOS transistor is coupled to the ground voltage;
a fourth inverter for receiving the comparison signal to generate a fourth inverting signal; and
a fourth NMOS transistor having a gate, source, and drain, wherein the drain of the fourth NMOS transistor is coupled to the drain of the fourth PMOS transistor, the gate of the fourth NMOS transistor receives the fourth inverting signal, and the source of the fourth NMOS transistor is coupled to the ground voltage.

7. The automatic substrate biasing circuit as claimed in claim 1, wherein the switching circuit comprises:
a fifth PMOS transistor having a gate, source, base and drain, wherein the gate of the fifth PMOS transistor receives the first control signal, the source and the base of the fifth PMOS transistor are jointly coupled to the substrate voltage signal, and the drain of the fifth PMOS transistor is coupled to the first voltage source; and
a sixth PMOS transistor having a gate, source, base and drain, wherein the gate of the sixth PMOS transistor receives the second control signal, the source and the base of the sixth PMOS transistor are jointly coupled to the substrate voltage signal, and the drain of the sixth PMOS transistor is coupled to the second voltage source.
